(19) United States
(12) Patent Application Publication
(10) Pub. No.: US 2025/0275584 A1
(43) Pub. Date: Sep. 4, 2025

(54) METHOD FOR MANUFACTURING SENSOR FOR AEROSOL-GENERATING DEVICE

(71) Applicant: Philip Morris Products S.A., Neuchatel (CH)

(72) Inventors: Riccardo RIVA REGGIORI, Lausanne (CH); Alexandra SEREDA, Zurich (CH); Serge LOPEZ, Nantes (FR); Edward BRANHAM, Hendersonville, NC (US); Matthew John LAWRENSON, Chesterfield, VA (US)

(73) Assignee: Philip Morris Products S.A., Neuchatel (CH)

(21) Appl. No.: 18/858,067

(22) PCT Filed: Jun. 14, 2023
(86) PCT No.: PCT/EP2023/065934

§ 371 Date: Oct. 18, 2024

(30) Foreign Application Priority Data
Jun. 17, 2022 (EP) 22179602.2

(51) Int. Cl. A24F 40/51; A24F 40/70; G01F 15/00; G01J 3/28; G01K 1/14; G01L 9/02; H05K 1/18

(52) U.S. Cl. CPC A24F 40/51; A24F 40/70; G01F 15/00; G01J 3/28; G01K 1/14; G01L 9/02; H05K 1/181; H05K 2201/10151

(57) ABSTRACT

A method for manufacturing a sensor for an aerosol-generating device is provided, the sensor formed from at least three sensor components, the method including: providing a layer of a flexible dielectric substrate; printing or mounting a first sensor component on a first location of the flexible dielectric substrate; printing or mounting a second sensor component on a second location of the flexible dielectric substrate, the second location being different from the first location; printing or mounting a third sensor component on a third location of the flexible dielectric substrate, the third location being different from the second location and from the first location; and wrapping or folding the flexible dielectric substrate such that three layers of the flexible dielectric substrate are formed, such that the first location, the second location, and the third location overlie each other thereby forming the sensor.

The present invention relates to a method for manufacturing a 3D sensor for an aerosol-generating device. The present invention further relates to a 3D sensor used in an aerosol-generating device. The present invention further relates to an aerosol-generating device comprising a 3D sensor.

It is known to provide an aerosol-generating device for generating an inhalable vapor. Such devices may heat aerosol-forming substrate to a temperature at which one or more components of the aerosol-forming substrate are volatilised without burning the aerosol-forming substrate. Aerosol-forming substrate may be provided as part of an aerosol-generating article. The aerosol-generating article may have a rod shape for insertion of the aerosol-generating article into a cavity, such as a heating chamber, of the aerosol-generating device. A heating element may be arranged in or around the heating chamber for heating the aerosol-forming substrate once the aerosol-generating article is inserted into the heating chamber of the aerosol-generating device. The aerosol-generating device comprises multiple electronic components such as a controller for controlling the operation of the heating element. Also, one or more sensors may be employed such as a temperature sensor, which output may be used to control operation of the hearing element. Housing any of these components in the aerosol-generating device may be challenging, as the aerosol-generating device should have a shape close to a conventional cigarette.

It would be desirable to have an improved method for manufacturing of a sensor for an aerosol-generating device. It would be desirable to have a method for manufacturing of a sensor for an aerosol-generating device with improved form factor for an aerosol-generating device.

According to an embodiment of the invention there is provided a method for manufacturing a sensor for an aerosol-generating device, wherein the method may comprise any of the following steps:
providing a layer of a flexible dielectric substrate,
printing or mounting a first sensor component on a first location of the flexible dielectric substrate,
printing or mounting a second sensor component on a second location of the flexible dielectric substrate, wherein the second location is different from the first location, and
printing or mounting a third sensor component on a third location of the flexible dielectric substrate, wherein the third location is different from the second location and from the first location,
wrapping or folding the flexible dielectric substrate such that three layers of the flexible dielectric substrate are formed, wherein the first location, the second location and the third location overlie each other thereby forming a sensor.

According to an embodiment of the invention there is provided a method for manufacturing a sensor for an aerosol-generating device, the method comprising:
providing a layer of a flexible dielectric substrate,
printing or mounting a first sensor component on a first location of the flexible dielectric substrate,
printing or mounting a second sensor component on a second location of the flexible dielectric substrate, wherein the second location is different from the first location, and
printing or mounting a third sensor component on a third location of the flexible dielectric substrate, wherein the third location is different from the second location and from the first location,
wrapping or folding the flexible dielectric substrate such that three layers of the flexible dielectric substrate are formed, wherein the first location, the second location and the third location overlie each other thereby forming a sensor.

The sensor may be a 3D sensor.

Manufacturing the 3D sensor in this way improves the form factor of the sensor. For example, the aerosol-generating device may have a cavity acting as a heating chamber. The cavity may be a hollow cylindrical cavity. It may be necessary or beneficial to arrange the sensor at a point around the periphery of the cavity. The method as described herein may create a tubular structure comprising the wrapped flexible dielectric substrate and the sensor components thereby creating a 3D sensor that can be optimally arranged surrounding the cavity of the aerosol-generating device.

The flexible dielectric substrate may be a polyimide sheet. The flexible dielectric substrate may be shaped to conform to the perimeter of the cavity of the aerosol-generating device.

The flexible dielectric substrate may be wrapped at least two times. Preferably, the flexible dielectric substrate may be wrapped at least three times. After the wrapping of the flexible dielectric substrate, at least three layers of the flexible dielectric substrate may overlie each other. The flexible dielectric substrate may be wrapped such that the flexible dielectric substrate afterwards has a hollow tubular shape. The flexible dielectric substrate may have a cylindrical shape after the wrapping step.

During the wrapping of the flexible dielectric substrate, each layer of the flexible dielectric substrate may be attached to one or both of the respective inner layer and outer layer. Exemplarily, the second layer of the flexible dielectric substrate may be attached to the first layer of the flexible dielectric substrate. The third layer of the flexible dielectric substrate may be attached to the second layer of the flexible dielectric substrate. The first layer of the flexible dielectric substrate may be the innermost layer. The third layer of the flexible dielectric substrate may be the outermost layer. The second layer of the flexible dielectric substrate may be the middle layer. The second layer of the flexible dielectric substrate may be sandwiched between the first layer of the flexible dielectric substrate and the third layer of the flexible dielectric substrate.

The formed 3D sensor may extend between the three layers of the flexible dielectric substrate. The 3D sensor may radially extend between the three layers of the flexible dielectric substrate. The radial direction may be perpendicular to a tangential direction defined by the surface of the outermost layer of the flexible dielectric substrate.

One or more of the first sensor component may be an electrical sensor component, the second sensor component may be an electrical sensor component and the third sensor component may be an electrical sensor component.

Exemplary electrical components are a resistor, a capacitor, an inductor, a microprocessor, electronic circuitry, joining circuitry, a cavity, a stud, and a heat sink.

One or more of the first, second and third sensor component may comprise a controller.

The controller may be configured to receive the output of the 3D sensor. The controller may be configured to control operation of the 3D sensor. The controller may comprise or may be a sensor logic unit. The controller may be electrically connected to one or more of the first, second and third sensor component via electrically conductive tracks.

One or more of the first, second and third sensor components may be unfunctional before being wrapped or folded. In other words, two or more of the first, second and third sensor components may become functional after being wrapped or folded. Two or more of the first, second and third sensor components may form a functional sensor after being wrapped or folded.

The 3D sensor may comprise a pressure sensor.

The 3D sensor may be a pressure sensor.

The 3D sensor may be configured as a pressure 3D sensor to measure the pressure of the air inside the aerosol-generating device which is drawn through an airflow path of the device by a user during a puff. The 3D sensor may be configured to measure a pressure difference or pressure drop between the pressure of ambient air outside of the aerosol-generating device and of the air which is drawn through the device by the user. The pressure of the air may be detected at an air inlet, a mouthpiece of the device, a cavity, a heating chamber or any other passage or chamber within the aerosol-generating device, through which the air flows. When the user draws on the aerosol-generating device, a negative pressure or vacuum is generated inside the device, wherein the negative pressure may be detected by the pressure 3D sensor. The term “negative pressure” is to be understood as a pressure which is relatively lower than the pressure of ambient air. In other words, when the user draws on the device, the air which is drawn through the device has a pressure which is lower than the pressure off ambient air outside of the device. The initiation of the puff may be detected by the pressure 3D sensor if the pressure difference exceeds a predetermined threshold.

One of the first, second and third sensor component may comprise a hermetically sealed cavity. A different one of the first, second and third sensor component may comprise a pressure sensitive resistor.

The pressure sensor of the 3D sensor may be formed by the hermetically sealed cavity and the pressure sensitive resistor. The second sensor component may comprise the hermetically sealed cavity. The hermetically sealed cavity may be arranged on the second location of the flexible dielectric substrate. The first sensor component may comprise a cavity support on the first location of the flexible dielectric substrate. The hermetically sealed cavity may supported on the cavity support. The third sensor component may comprise the pressure sensitive resistor. The pressure sensitive resistor may be arranged on the hermetically sealed cavity.

When ambient air is drawn into the aerosol-generating device by a user, a negative pressure is created in the airflow path. The 3D sensor may detect this negative pressure as the hermetically sealed cavity may expand. The expansion of the hermetically sealed cavity may take place, since the air inside of the hermetically sealed cavity has a—relatively-higher pressure than the air being drawn though the airflow channel and having a negative pressure. The expansion of the hermetically sealed cavity may be detected by the pressure sensitive resistor. Due to the arrangement of the pressure sensitive resistor on the hermetically sealed cavity, the pressure sensitive resistor may be pressurized when the hermetically sealed cavity expands. This may lead to a change of the resistance of the pressure sensitive resistor. This change in resistance may be measured by the controller as described herein. The change in resistance may be indicative of a draw of a user.

As an alternative to providing the hermetically sealed cavity as part of the second sensor component, the hermetically sealed cavity may be formed between the three layers during the wrapping or folding of the flexible dielectric substrate. Exemplarily, the first sensor component may comprise a base of the hermetically sealed cavity, the second sensor component may comprise sidewalls of the hermetically sealed cavity and the third sensor component may comprise a top wall of the hermetically sealed cavity. The complete hermetically sealed cavity may thus be formed by wrapping or folding the three layers of the flexible dielectric substrate on top of each other such that the base of the hermetically sealed cavity is formed by the innermost layer having the first sensor component. The sidewalls of the hermetically sealed cavity may be formed by the second sensor component as the middle layer and the top of the hermetically sealed cavity may be formed by the third sensor component as the outermost component.

The top of the hermetically sealed cavity may comprise or may be formed by a flexible diaphragm. The flexible diaphragm may enable that the expansion of the hermetically sealed cavity takes place. The pressure sensitive resistor may be arranged on the flexible diaphragm. The pressure sensitive resistor may be overlaid over the flexible diaphragm.

Alternatively, only the first and second sensor components may be used to form the hermetically sealed cavity or only the second and third sensor components may be used to form the hermetically sealed cavity.

During wrapping, the first location may be on the innermost layer of the flexible dielectric substrate. The second location may be on the middle layer of the flexible dielectric substrate. The third location may be on the outermost layer of the flexible dielectric substrate.

The 3D sensor may comprise a spectrometer.

The 3D sensor may be a spectrometer.

One of the first, second and third sensor component may comprise a light source. One of the first, second and third sensor component may comprise a detector.

Exemplarily, the first sensor component may comprise the light source and the third sensor component may comprise the detector.

The spectrometer may be configured to detect gas.

One of the first, second and third sensor component may comprise parts of a spectrometer cavity such that the spectrometer cavity is formed after the wrapping or folding step.

Exemplarily, the first sensor component may comprise a base of the spectrometer cavity, the second sensor component may comprise sidewalls of the spectrometer cavity and the third sensor component may comprise a top wall of the spectrometer cavity. Alternatively, only the first sensor component and the second sensor component may comprise parts of the spectrometer cavity or only the second sensor component and the third sensor component may comprise parts of the spectrometer cavity.

The base of the spectrometer cavity may comprise a first hole. The top wall of the spectrometer cavity may comprise a second hole. The base of the spectrometer cavity may comprise a first shutter able to open and close the first hole. The top wall of the spectrometer cavity may comprise a second shutter able to open and close the second hole. If the first and second shutters are closed, the spectrometer cavity is sealed. If the first and second shutters are open, gas can enter the spectrometer cavity. One or both of the first and second shutters may be configured to open when subjected to a negative pressure. In other words, one or both of the first and second shutters may be configured to open during a draw of a user.

The light source and the detector may be arranged in the spectrometer cavity. When the first and second shutters are open, gas can enter the spectrometer cavity. This gas may influence the detector output. The detector output may be influenced by, for example, scattering of the light of the light source by the gas inside of the spectrometer cavity.

One or both of the light source and the detector may be electrically connected to a controller as described herein. As the light source and the detector are arranged within the spectrometer cavity, the electrical connection may be facilitated by electrically conductive tracks connecting one or both of the light source and the detector via through-substrate connectors. The through-substrate connectors may run through one or more of the first, second and third layers of the flexible dielectric substrate.

The 3D sensor may comprise a temperature sensor.

The 3D sensor may be a temperature sensor.

One of the first, second and third sensor component may comprise a thermally sensitive material. A different one of the first, second and third sensor component may comprise a pressure sensitive resistor.

During a temperature change, the thermally sensitive material may expand or contract. This expansion or contraction may pressurize the pressure sensitive resistor. The resulting resistance change may be detected by a controller as described herein.

For example, the first sensor component may comprise the thermally sensitive material and the third sensor component may comprise the pressure sensitive resistor or vice versa. The second sensor component may comprise a through hole. The thermally sensitive material may extend through the through hole. The pressure sensitive resistor may be arranged on or abutting the pressure sensitive resistor.

The thermally sensitive material may be attached via pins to the flexible dielectric substrate. On an opposite side of the layers of the flexible dielectric substrate, a plate may be arranged. The pins may penetrate through the flexible dielectric substrate and connected with the plate so as to secure the thermally sensitive material in place.

The temperature sensor may comprise at least two, preferably at least three, separate temperature sensors arranged at different locations of the wrapped or folded flexible dielectric substrate. Preferably, only a single controller is provided in this embodiment and all of the temperature sensors are connected to the single controller. When the 3D-sensor is arranged around a cavity of an aerosol-generating device, the temperature sensors may be arranged to measure the temperature in different portions of the cavity.

The 3D sensor may comprise a flow sensor. The flow sensor may be configured to detect an airflow through the airflow channel of the aerosol-generating device so as to detect a draw of a user.

One of the first, second and third sensor component may comprise a free-standing cantilever structure. One of the first, second and third sensor component may comprise two separate electrodes electrically contacting the free-standing cantilever structure. As air travels over the free-standing cantilever structure, the resistance across the two separate electrodes may change. The sensor's micro, or nano, electronics architecture may be done in a way that at least two surfaces are sensitive to changes in the environmental conditions, preferably the external air flow in this case. The two surfaces of the electrodes may work as poles, wherein the electrical characteristics may vary when the temperature and/or humidity varies. As an example, electro humidity sensors can incorporate polyaniline nanofibers (PAni) which have high response into humidity changes, rapidly varying its electrical resistance. The same occurs using a PVA nanomesh humidity sensor structure. Using any of those materials, PAni or PVA nanomesh, it is possible to assemble/build the sensors as described herein, such as presented in the below described Figures (e.g. 2A and 4A).

This resistance change may be detected by a controller as described herein. The resistance change by be indicative of a draw of a user.

The 3D sensor may comprise one or more of a humidity sensor, a chemical composition sensor and a biological signal sensor. An exemplary humidity sensor may comprise a Zinc oxide nanostructure layer deposition as a coating for humidity sensing. The sensor may be assembled, as described herein, as a free-standing cantilever structure. The sensor can be manufactured using thin-film technology. In this case the resistance of the applied coated films may decrease with increasing relative humidity rapidly and in a highly reliable way, as the electrical resistance may change by more than four of magnitude when ZnO nanomaterials thin structures are exposed from standard room conditions of about 60% relative humidity to a moisture pulse of 95% relative humidity, giving a wide range of possibilities to measure gradients with enough accuracy for humidity sensing.

The free-standing cantilever structure may enable that the flexible surface of the two electrodes acts as a membrane which micro-deforms upon the air flow conditions due to elementary fluid mechanics and the characteristics of the material comprising the membrane, which by varying its shape when flexing also changes its electrical characteristics.

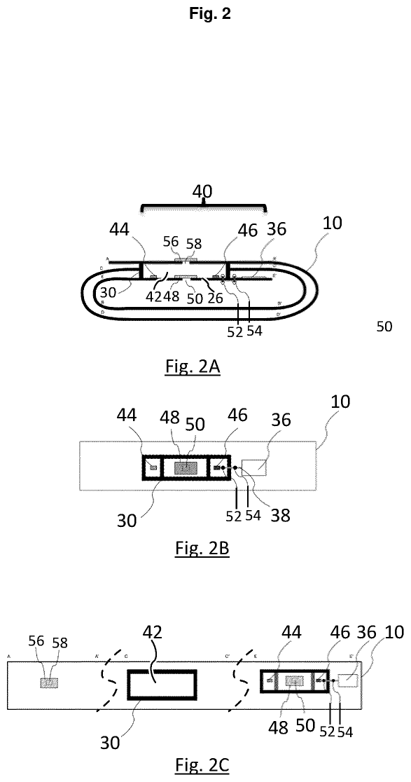

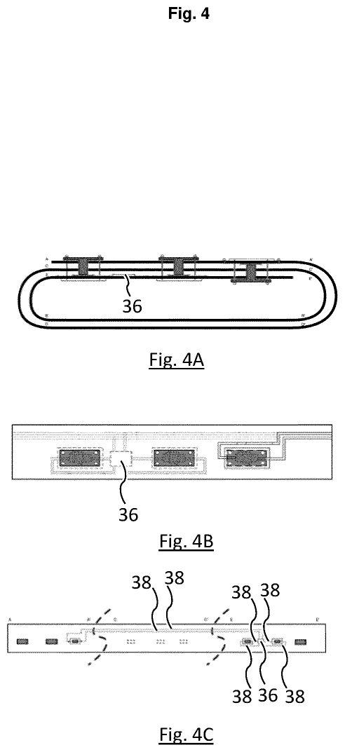

Due to the concept of designing the sensors based on overlapping thin-film layers as described herein, it's then possible that the different layers may have different characteristics and sensing in different “directions”. As an example, the assemblies presented in below described FIG. 2A or FIG. 4A may enable that once the layers are arranged overlapping, thereby forming the sensor(s) structure, the sensor may sense in the inner direction, sensing the inner area/volume, as well as in the outer direction, sensing the outer area/volume.

The invention further relates to a 3D sensor used in an aerosol-generating device, wherein the 3D sensor is manufactured according to any method described herein.

The invention further relates to an aerosol-generating device comprising the 3D sensor as described herein.

As used herein, the terms ‘proximal’, ‘distal’, ‘downstream’ and ‘upstream’ are used to describe the relative positions of components, or portions of components, of the aerosol-generating device in relation to the direction in which a user draws on the aerosol-generating device during use thereof.

The aerosol-generating device may comprise a mouth end through which in use an aerosol exits the aerosol-generating device and is delivered to a user. The mouth end may also be referred to as the proximal end. In use, a user draws on the proximal or mouth end of the aerosol-generating device in order to inhale an aerosol generated by the aerosol-generating device. The aerosol-generating device comprises a distal end opposed to the proximal or mouth end. The proximal or mouth end of the aerosol-generating device may also be referred to as the downstream end and the distal end of the aerosol-generating device may also be referred to as the upstream end. Components, or portions of components, of the aerosol-generating device may be described as being upstream or downstream of one another based on their relative positions between the proximal, downstream or mouth end and the distal or upstream end of the aerosol-generating device.

As used herein, an ‘aerosol-generating device’ relates to a device that interacts with an aerosol-forming substrate to generate an aerosol. The aerosol-forming substrate may be part of an aerosol-generating article, for example part of a smoking article. An aerosol-generating device may be a smoking device that interacts with an aerosol-forming substrate of an aerosol-generating article to generate an aerosol that is directly inhalable into a user's lungs thorough the user's mouth. An aerosol-generating device may be a holder. The device may be an electrically heated smoking device. The aerosol-generating device may comprise a housing, electric circuitry, a power supply, a heating chamber and a heating element.

As used herein with reference to the present invention, the term ‘smoking’ with reference to a device, article, system, substrate, or otherwise does not refer to conventional smoking in which an aerosol-forming substrate is fully or at least partially combusted. The aerosol-generating device of the present invention is arranged to heat the aerosol-forming substrate to a temperature below a combustion temperature of the aerosol-forming substrate, but at or above a temperature at which one or more volatile compounds of the aerosol-forming substrate are released to form an inhalable aerosol.

The aerosol-generating device may comprise electric circuitry. The electric circuitry may comprise a microprocessor, which may be a programmable microprocessor. The microprocessor may be part of a controller. The electric circuitry may comprise further electronic components. The electric circuitry may be configured to regulate a supply of power to the heating element. Power may be supplied to the heating element continuously following activation of the aerosol-generating device or may be supplied intermittently, such as on a puff-by-puff basis. The power may be supplied to the heating element in the form of pulses of electrical current. The electric circuitry may be configured to monitor the electrical resistance of the heating element, and preferably to control the supply of power to the heating element dependent on the electrical resistance of the heating element. The electric circuitry may comprise the 3D sensor and the controller electrically connected with the 3D sensor. The aerosol-generating device may be operated by the controller based upon the output of the 3D sensor.

The aerosol-generating device may comprise a power supply, typically a battery, within a main body of the aerosol-generating device. In one embodiment, the power supply is a Lithium-ion battery. Alternatively, the power supply may be a Nickel-metal hydride battery, a Nickel cadmium battery, or a Lithium based battery, for example a Lithium-Cobalt, a Lithium-Iron-Phosphate, Lithium Titanate or a Lithium-Polymer battery. As an alternative, the power supply may be another form of charge storage device such as a capacitor. The power supply may require recharging and may have a capacity that enables to store enough energy for one or more usage experiences; for example, the power supply may have sufficient capacity to continuously generate aerosol for a period of around six minutes or for a period of a multiple of six minutes. In another example, the power supply may have sufficient capacity to provide a predetermined number of puffs or discrete activations of the heating element.

The cavity of the aerosol-generating device may have an open end into which the aerosol-generating article is inserted. The open end may be a proximal end. The cavity may have a closed end opposite the open end. The closed end may be the base of the cavity. The closed end may be closed except for the provision of air apertures arranged in the base. The base of the cavity may be flat. The base of the cavity may be circular. The base of the cavity may be arranged upstream of the cavity. The open end may be arranged downstream of the cavity. The cavity may have an elongate extension. The cavity may have a longitudinal central axis. A longitudinal direction may be the direction extending between the open and closed ends along the longitudinal central axis. The longitudinal central axis of the cavity may be parallel to the longitudinal axis of the aerosol-generating device.

The cavity may be configured as a heating chamber. The cavity may have a cylindrical shape. The cavity may have a hollow cylindrical shape. The cavity may have a shape corresponding to the shape of the aerosol-generating article to be received in the cavity. The cavity may have a circular cross-section. The cavity may have an elliptical or rectangular cross-section. The cavity may have an inner diameter corresponding to the outer diameter of the aerosol-generating article. The flexible dielectric substrate with the sensor components forming the 3D sensor may be arranged at least partly, preferably fully, surrounding the cavity.

An airflow channel may run through the cavity. Ambient air may be drawn into the aerosol-generating device, into the cavity and towards the user through the airflow channel. Downstream of the cavity, a mouthpiece may be arranged or a user may directly draw on the aerosol-generating article. The airflow channel may extend through the mouthpiece.

In any of the aspects of the disclosure, the heating element may comprise an electrically resistive material. Suitable electrically resistive materials include but are not limited to: semiconductors such as doped ceramics, electrically “conductive” ceramics (such as, for example, molybdenum disilicide), carbon, graphite, metals, metal alloys and composite materials made of a ceramic material and a metallic material. Such composite materials may comprise doped or undoped ceramics. Examples of suitable doped ceramics include doped silicon carbides. Examples of suitable metals include titanium, zirconium, tantalum platinum, gold and silver. Examples of suitable metal alloys include stainless steel, nickel-, cobalt-, chromium-, aluminium-titanium-zirconium-, hafnium-, niobium-, molybdenum-, tantalum-, tungsten-, tin-, gallium-, manganese-, gold-and iron-containing alloys, and super-alloys based on nickel, iron, cobalt, stainless steel, Timetal® and iron-manganese-aluminium based alloys. In composite materials, the electrically resistive material may optionally be embedded in, encapsulated or coated with an insulating material or vice-versa, depending on the kinetics of energy transfer and the external physicochemical properties required.

As described, in any of the aspects of the disclosure, the heating element may be part of an aerosol-generating device. The aerosol-generating device may comprise an internal heating element or an external heating element, or both internal and external heating elements, where “internal” and “external” refer to the aerosol-forming substrate. An internal heating element may take any suitable form. For example, an internal heating element may take the form of a heating blade. Alternatively, the internal heater may take the form of a casing or substrate having different electro-conductive portions, or an electrically resistive metallic tube. Alternatively, the internal heating element may be one or more heating needles or rods that run through the center of the aerosol-forming substrate. Other alternatives include a heating wire or filament, for example a Ni—Cr (Nickel-Chromium), platinum, tungsten or alloy wire or a heating plate. Optionally, the internal heating element may be deposited in or on a rigid carrier material. In one such embodiment, the electrically resistive heating element may be formed using a metal having a defined relationship between temperature and resistivity. In such an exemplary device, the metal may be formed as a track on a suitable insulating material, such as ceramic material, and then sandwiched in another insulating material, such as a glass. Heaters formed in this manner may be used to both heat and monitor the temperature of the heating elements during operation.

An external heating element may take any suitable form. For example, an external heating element may take the form of one or more flexible heating foils on a dielectric substrate, such as polyimide. The flexible heating foils can be shaped to conform to the perimeter of the substrate receiving cavity. Alternatively, an external heating element may take the form of a metallic grid or grids, a flexible printed circuit board, a molded interconnect device (MID), ceramic heater, flexible carbon fibre heater or may be formed using a coating technique, such as plasma vapour deposition, on a suitable shaped substrate. An external heating element may also be formed using a metal having a defined relationship between temperature and resistivity. In such an exemplary device, the metal may be formed as a track between two layers of suitable insulating materials. An external heating element formed in this manner may be used to both heat and monitor the temperature of the external heating element during operation.

As an alternative to an electrically resistive heating element, the heating element may be configured as an induction heating element. The induction heating element may comprise an induction coil and a susceptor. In general, a susceptor is a material that is capable of generating heat, when penetrated by an alternating magnetic field. When located in an alternating magnetic field. If the susceptor is conductive, then typically eddy currents are induced by the alternating magnetic field. If the susceptor is magnetic, then typically another effect that contributes to the heating is commonly referred to hysteresis losses. Hysteresis losses occur mainly due to the movement of the magnetic domain blocks within the susceptor, because the magnetic orientation of these will align with the magnetic induction field, which alternates. Another effect contributing to the hysteresis loss is when the magnetic domains will grow or shrink within the susceptor. Commonly all these changes in the susceptor that happen on a nano-scale or below are referred to as “hysteresis losses”, because they produce heat in the susceptor. Hence, if the susceptor is both magnetic and electrically conductive, both hysteresis losses and the generation of eddy currents will contribute to the heating of the susceptor. If the susceptor is magnetic, but not conductive, then hysteresis losses will be the only means by which the susceptor will heat, when penetrated by an alternating magnetic field. According to the invention, the susceptor may be electrically conductive or magnetic or both electrically conductive and magnetic. An alternating magnetic field generated by one or several induction coils heat the susceptor, which then transfers the heat to the aerosol-forming substrate, such that an aerosol is formed. The heat transfer may be mainly by conduction of heat. Such a transfer of heat is best, if the susceptor is in close thermal contact with the aerosol-forming substrate.

As used herein, the term ‘aerosol-generating article’ refers to an article comprising an aerosol-forming substrate that is capable of releasing volatile compounds that can form an aerosol. For example, an aerosol-generating article may be a smoking article that generates an aerosol that is directly inhalable into a user's lungs through the user's mouth. An aerosol-generating article may be disposable.

As used herein, the term ‘aerosol-forming substrate’ relates to a substrate capable of releasing one or more volatile compounds that can form an aerosol. Such volatile compounds may be released by heating the aerosol-forming substrate. An aerosol-forming substrate may conveniently be part of an aerosol-generating article or smoking article.

The aerosol-forming substrate may be a solid aerosol-forming substrate. The aerosol-forming substrate may comprise both solid and liquid components. The aerosol-forming substrate may comprise a tobacco-containing material containing volatile tobacco flavour compounds which are released from the substrate upon heating. The aerosol-forming substrate may comprise a non-tobacco material. The aerosol-forming substrate may comprise an aerosol former that facilitates the formation of a dense and stable aerosol. Examples of suitable aerosol formers are glycerine and propylene glycol. The aerosol-generating substrate preferably comprises homogenised tobacco material, an aerosol-former and water. Providing homogenised tobacco material may improve aerosol generation, the nicotine content and the flavour profile of the aerosol generated during heating of the aerosol-generating article. Specifically, the process of making homogenised tobacco involves grinding tobacco leaf, which more effectively enables the release of nicotine and flavours upon heating.

For brevity, if only the term “wrapped” or “wrapping” is used for the wrapping or folding step, this also encompasses the option of “folded” or “folding”.

Below, there is provided a non-exhaustive list of non-limiting examples. Any one or more of the features of these examples may be combined with any one or more features of another example, embodiment, or aspect described herein.

Example ex1. A method for manufacturing a 3D sensor for an aerosol-generating device, the method comprising:
providing a layer of a flexible dielectric substrate,
printing or mounting a first sensor component on a first location of the flexible dielectric substrate,
printing or mounting a second sensor component on a second location of the flexible dielectric substrate, wherein the second location is different from the first location, and
printing or mounting a third sensor component on a third location of the flexible dielectric substrate, wherein the third location is different from the second location and from the first location,
wrapping or folding the flexible dielectric substrate such that three layers of the flexible dielectric substrate are formed, wherein the first location, the second location and the third location overlie each other thereby forming a 3D sensor.

Example ex2. The method according to example ex1, wherein one or more of the first sensor component is an electrical sensor component, the second sensor component is an electrical sensor component and the third sensor component is an electrical sensor component.

Example ex3. The method according to any of the preceding examples, wherein one or more of the first, second and third sensor component comprises a controller.

Example ex4. The method according to any of the preceding examples, wherein one or more of the first, second and third sensor component comprises one or more of a resistor, a capacitor, an inductor, a microprocessor, electronic circuitry, joining circuitry, a cavity, a stud, and a heat sink.

Example ex5. The method according to any of the preceding examples, wherein the method comprises a further step after the wrapping or folding step, wherein the further step is attaching an electrical component, preferably electrically conductive tracks, to the 3D sensor.

Example ex6. The method according to the preceding example, wherein the attachment is facilitated using one or more of gluing, friction welding, friction bonding and ultrasonic bonding.

Example ex7. The method according to any of the two preceding examples, wherein the attachment is facilitated using one or more of glue, epoxy, wire and solder.

Example ex8. The method according to any of the preceding examples, wherein the 3D sensor comprises a pressure sensor.

Example ex9. The method according to the preceding example, wherein one of the first, second and third sensor component comprises a hermetically sealed cavity, and wherein a different one of the first, second and third sensor component comprises a pressure sensitive resistor.

Example ex10. The method according to any of the preceding examples, wherein the 3D sensor comprises a spectrometer.

Example ex11. The method according to the preceding example, wherein one of the first, second and third sensor component comprises a light source, and wherein one of the first, second and third sensor component comprises a detector.

Example ex12. The method according to any of the preceding examples, wherein the 3D sensor comprises a temperature sensor.

Example ex13. The method according to the preceding example, wherein one of the first, second and third sensor component comprises a thermally sensitive material, and wherein a different one of the first, second and third sensor component comprises a pressure sensitive resistor.

Example ex14. The method according to any of the two preceding examples, wherein the temperature sensor comprises at least two, preferably at least three, separate temperature sensors arranged at different locations of the wrapped or folded flexible dielectric substrate.

Example ex15. The method according to any of the preceding examples, wherein the 3D sensor comprises a flow sensor.

Example ex16. The method according to the preceding example, wherein one of the first, second and third sensor component comprises a free-standing cantilever structure, and wherein one of the first, second and third sensor component comprises two separate electrodes electrically contacting the free-standing cantilever structure.

Example ex17. The method according to any of the preceding examples, wherein the 3D sensor comprises one or more of a humidity sensor, a chemical composition sensor and a biological signal sensor.

Example ex18. A 3D sensor used in an aerosol-generating device, wherein the 3D sensor is manufactured according to any of the preceding examples.

Example ex19. An aerosol-generating device comprising the 3D sensor of the preceding example.

Features described in relation to one embodiment may equally be applied to other embodiments of the invention.

The invention will be further described, by way of example only, with reference to the accompanying drawings in which:

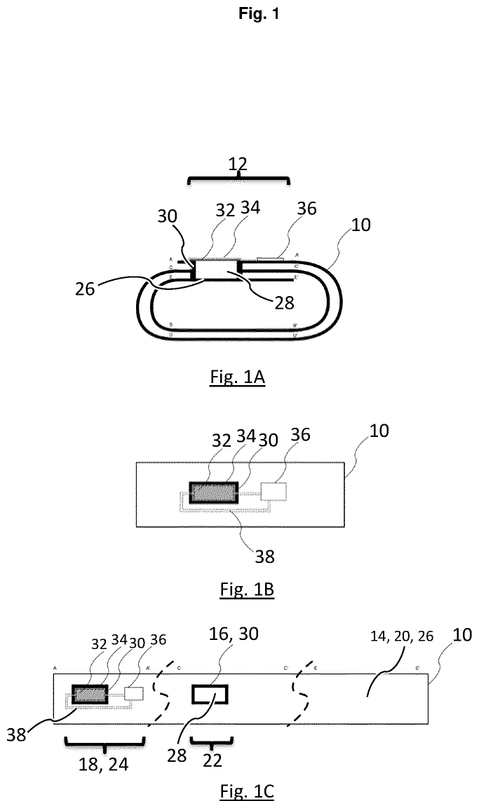

FIGS. 1A to 1C show a 3D sensor comprising a pressure sensor;

FIGS. 2A to 2C show a 3D sensor comprising a spectrometer;

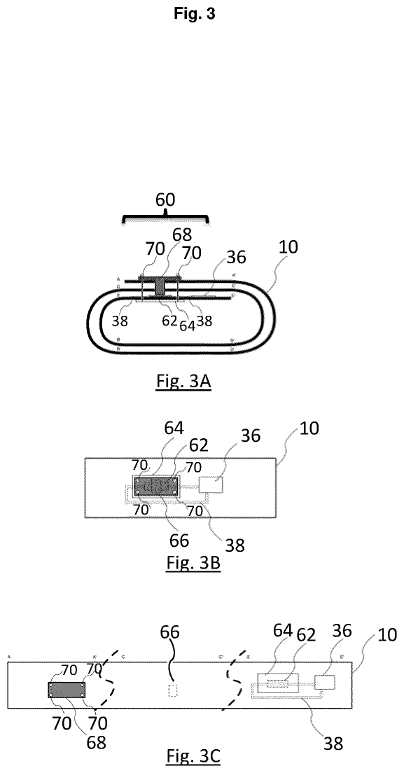

FIGS. 3A to 3C show a 3D sensor comprising a temperature sensor;

FIGS. 4A to 4C show a 3D sensor comprising multiple temperature sensors; and

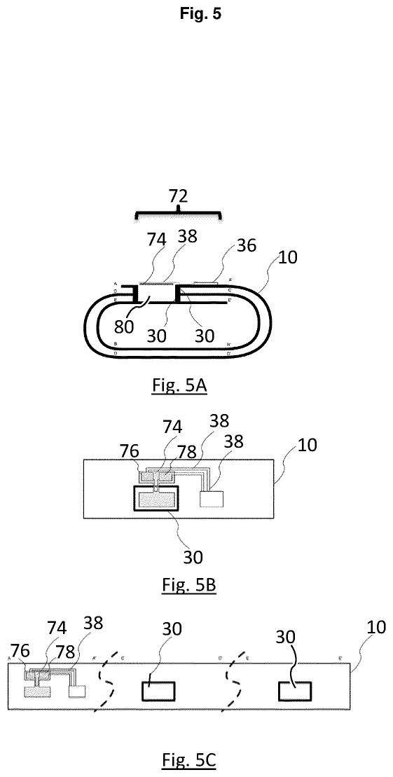

FIGS. 5A to 5C show a 3D sensor comprising a flow sensor.

FIG. 1A shows a 3D sensor after being wrapped. The 3D sensor comprises a flexible dielectric substrate 10. The flexible dielectric substrate 10 is wrapped such that three layers A-A′, C-C′ and E-E′ of the flexible dielectric substrate 10 are arranged over each other in the area where the 3D sensor is formed.

The 3D sensor shown in FIGS. 1A to 1C comprises a pressure sensor 12. The pressure sensor 12 is formed by a first sensor component 14, a second sensor component 16 and a third sensor component 20.

The first sensor component 14 is arranged at a first location of the flexible dielectric substrate 20. The second sensor component 16 is arranged at a second location of the flexible dielectric substrate 22. The third sensor component 20 is arranged at a third location of the flexible dielectric substrate 24.

The first sensor component 14 in the pressure sensor 12 embodiment shown in FIG. 1 is a base 26 of a hermetically sealed cavity 28. The second sensor component 16 comprises walls 30, particularly sidewalls 30, of the hermetically sealed cavity 28. The third sensor component 20 comprise a flexible diaphragm 32 forming the top wall of the hermetically sealed cavity 28, a pressure sensitive resistor 34 overlying the flexible diaphragm 32, walls 30 of the hermetically sealed cavity 28, a controller 36 and electrically conductive tracks 38 electrically connecting the pressure sensitive resistor 34 with the controller 36.

FIG. 1A shows the final 3D sensor. FIG. 1B shows the third sensor component 20 or a top view of the wrapped 3D sensor and FIG. 1C shows the 3D sensor before the wrapping step. This figure arrangement is consistent for FIGS. 1 to 5. FIG. 1C shows the individual first sensor component 14, second sensor component 16 and third sensor component 20 arranged on the flexible dielectric substrate 10. The functional pressure sensor 12 is formed only by wrapping the flexible dielectric substrate 10. Then, a change of pressure, particularly a negative pressure of air being drawn through an aerosol-generating system, leads to a deformation of the internal volume of the hermetically sealed cavity 28. This deformation leads to a bulging out of the flexible diaphragm 32 which leads to a resistance change in the pressure sensitive resistor 34. This resistance change is detected by the controller 36 and indicative of a draw of a user.

FIGS. 2A to 2C show the 3D sensor comprising a spectrometer 40. The embodiment shown in FIGS. 2A to 2C has many components similar to the embodiment shown in FIGS. 1A to 1C such as the flexible dielectric substrate 10, the wrapping and layering of the flexible dielectric substrate 10 and the controller 36. For brevity, the description of this and the following embodiments focusses on the differences while similar elements are not described and similar elements have the same reference signs in the figures.

The spectrometer 40 of FIGS. 2A to 2C has a spectrometer cavity 42 having walls 30. The first sensor component 14 at the first location of the flexible dielectric substrate 20 comprises walls 30, preferably a base 26, of the spectrometer cavity 42 and the second sensor component 16 at the second location of the flexible dielectric substrate 22 comprises walls 30, preferably side walls 30, of the spectrometer cavity 42. The first sensor component 14 further comprises a light source 44 and a detector 46, both of which are arranged on the base 26 of the spectrometer cavity 42 such that they are inside of the spectrometer cavity 42 after wrapping of the flexible dielectric substrate 10. The first sensor component 14 further comprises a first shutter 48 that is arranged over a base hole 50 arranged in the base 26 of the flexible dielectric substrate 10. The first sensor component 14 further comprises the controller 36 and a first through-substrate connector 52 and a second through-substrate connector 54. The first through-substrate connector 52 and the second through-substrate connector 54 together with the conductive tracks 38 are arranged to establish an electrical connection between the detector 46 and the controller 36.

The third sensor component 18 comprises a second shutter 56 that is arranged over a top hole 58 arranged at the third location of the flexible dielectric substrate 24.

After wrapping of the flexible dielectric substrate 10 as shown in FIG. 2A, the spectrometer cavity 42 is fully formed. The first shutter 48 and the second shutter 56 are arranged to allow air to enter the spectrometer cavity 42. The first shutter 48 and the second shutter 56 are arranged to allow air to enter the spectrometer cavity 42 during a pressure change, preferably during a negative pressure outside of the spectrometer cavity 42. Gas entering the spectrometer cavity 42 may be detected by the detector 46 as for example the scattering of the light from the light source 44 influences the light reaching the detector 46.

FIG. 2B shows the first sensor component 14 and the first location of the flexible dielectric substrate 20. FIG. 2C shows the first sensor component 14, the second sensor component 16 and the third sensor component 20 arranged on the flexible dielectric substrate 10 before the wrapping step. FIG. 2C alternatively shows a top view of the wrapped 3D sensor.

FIGS. 3A to 3C show the 3D sensor comprising a temperature sensor 60. Only the elements differing from the previous embodiments are described in the following. The first sensor component 14 of the temperature sensor 60 comprises a pressure sensitive resistor 62 and an attachment plate 64 at the first location of the flexible dielectric substrate 20.

The second sensor component 16 comprises a through hole 66 and the third sensor component 20 comprises a thermally sensitive material 68. Attachment pins 70 attach the thermally sensitive material 68 to the attachment plate 64 as shown in FIG. 3A.

After wrapping of the flexible dielectric substrate 10, the thermally sensitive material 68 is arranged adjacent or abutting the pressure sensitive resistor 62. A temperature change, particularly a temperature increase, of the thermally sensitive material 68 leads to an expansion of the thermally sensitive material 68. The expansion of the thermally sensitive material 68 leads to pressure being applied by the thermally sensitive material 68 to the pressure sensitive resistor 62. This leads to a resistance change of the pressure sensitive resistor 62 which can be detected by the controller 36.

FIGS. 4A to 4C show the 3D sensor comprising multiple temperature sensor 60s. Each of the temperature sensor 60s is configured similar to the temperature sensor 60 shown in FIGS. 3A to 3C. All of the exemplarily three temperature sensor 60s shown in FIGS. 4A to 4C are connected to a common controller 36 via conductive tracks 38.

FIGS. 5A to 5C show the 3D sensor comprising a flow sensor 72 or flow meter. The flow sensor 72 comprises a free-standing cantilever structure 74 having a first electrode 76 and a second electrode 78. The free-standing cantilever structure 74 is arranged above a cantilever cavity 80. The cantilever cavity 80 is formed by the first sensor component 14 and the second sensor component 16. The first sensor component 14 comprises the free-standing cantilever structure 74, the first electrode 76 and the second electrode 78. If air flows over the first electrode 76 and the second electrode 78, the resistance across the first electrode 76 and the second electrode 78 changes. This can be detected by the controller 36 being connected with the first electrode 76 and the second electrode 78 via conductive tracks 38.

1.-16. (canceled)

17. A method for manufacturing a sensor for an aerosol-generating device, the sensor formed from at least three sensor components, the method comprising:
providing a layer of a flexible dielectric substrate;
printing or mounting a first sensor component on a first location of the flexible dielectric substrate;
printing or mounting a second sensor component on a second location of the flexible dielectric substrate, the second location being different from the first location;
printing or mounting a third sensor component on a third location of the flexible dielectric substrate, the third location being different from the second location and from the first location; and
wrapping or folding the flexible dielectric substrate such that three layers of the flexible dielectric substrate are formed,
wherein the first location, the second location, and the third location overlie each other thereby forming the sensor.

18. The method according to claim 17, wherein one or more of the first sensor components is an electrical sensor component, the second sensor component is an electrical sensor component, and the third sensor component is an electrical sensor component.

19. The method according to claim 17, wherein one or more of the first, the second, and the third sensor components comprises a controller.

20. The method according to claim 17, wherein the sensor comprises a pressure sensor.

21. The method according to claim 20,
wherein one of the first, the second, and the third sensor components comprises a hermetically sealed cavity, and
wherein a different one of the first, the second, and the third sensor components further comprises a pressure sensitive resistor.

22. The method according to claim 17, wherein the sensor comprises a spectrometer.

23. The method according to claim 22,
wherein one of the first, the second, and the third sensor components comprises a light source, and
wherein one of the first, the second, and the third sensor components further comprises a detector.

24. The method according to claim 17, wherein the sensor comprises a temperature sensor.

25. The method according to claim 24,
wherein one of the first, the second, and the third sensor components comprises a thermally sensitive material, and
wherein a different one of the first, the second, and the third sensor components further comprises a pressure sensitive resistor.

26. The method according to claim 24, wherein the temperature sensor comprises at least two separate temperature sensors arranged at different locations of the wrapped or folded flexible dielectric substrate.

27. The method according to claim 24, wherein the temperature sensor comprises at least three separate temperature sensors arranged at different locations of the wrapped or folded flexible dielectric substrate.

28. The method according to claim 17, wherein the sensor comprises a flow sensor.

29. The method according to claim 28,
wherein one of the first, the second, and the third sensor components comprises a free-standing cantilever structure, and
wherein one of the first, the second, and the third sensor components further comprises two separate electrodes electrically contacting the free-standing cantilever structure.

30. The method according to claim 17, wherein the sensor comprises one or more of a humidity sensor, a chemical composition sensor, and a biological signal sensor.

31. The method according to claim 17, wherein the sensor is a 3D sensor.

32. A sensor used in an aerosol-generating device, wherein the sensor is manufactured according to the method of claim 17.

33. An aerosol-generating device comprising the sensor of claim 32.
